(19) United States
(12) Patent Application Publication
(10) Pub. No.: US 2026/0197568 A1
(43) Pub. Date: Jul. 9, 2026

(54) SENSOR PACKAGING STRUCTURE, SENSOR AND ELECTRONIC DEVICE

(71) Applicant: GOERTEK MICROELECTRONICS INC, Qingdao (CN)

(72) Inventors: Hao ZHANG, Qingdao (CN); Yonghua ZHANG, Qingdao (CN); Congcong ZHAO, Qingdao (CN)

(21) Appl. No.: 19/557,389

(22) Filed: Mar. 5, 2026

Related U.S. Application Data
(63) Continuation of application No. PCT/CN2024/127372, filed on Oct. 25, 2024.

(30) Foreign Application Priority Data
Sep. 26, 2023 (CN) 202311253567.5

(51) Int. Cl. H04R 1/02; B81B 7/00; H04R 1/04; H04R 1/06

(52) U.S. Cl. CPC H04R 1/021; B81B 7/0038; H04R 1/04; H04R 1/06; B81B 2201/0257; H04R 2201/003; H04R 2499/11

(57) ABSTRACT

A sensor packaging structure includes a housing, a substrate, a sensing component, and a waterproof membrane. The housing has an opening at one end, and the substrate covers the opening to form an encapsulation cavity with the housing. A first acoustic hole is formed in the substrate and communicates with the encapsulation cavity. The sensing component is accommodated in the encapsulation cavity and includes a mounting plate, a sensor chip, and a signal processing chip mounted side by side on the mounting plate, the sensor chip having a vibration cavity. A second acoustic hole is formed in the mounting plate to communicate the vibration cavity with the encapsulation cavity, and the second acoustic hole is offset from the first acoustic hole.

### CROSS-REFERENCE TO RELATED APPLICATIONS

This application is a continuation application of International Application No. PCT/CN2024/127372, filed on Oct. 25, 2024, which claims priority to Chinese Patent Application No. 202311253567.5, filed on Sep. 26, 2023. All of the above-mentioned applications are incorporated herein by reference in their entireties.

### TECHNICAL FIELD

The present application relates to the technical field of sensors, and in particular to a sensor packaging structure, a sensor, and an electronic device.

### BACKGROUND

At present, microphones as sensors have become standard components in electronic devices such as mobile phones, bracelets, watches, smart glasses, and earphones, and the performance of the sensor directly affects the performance of the electronic device. Signal-to-noise ratio (SNR) performance is a key indicator affecting sensor performance. In order to reduce noise, a common approach in existing sensor packaging structures is to keep the overall structural height unchanged while increasing the overall length of the structure, for example, increasing the length of the sensor packaging structure by 100 μm, so as to reduce the alignment deviation between the inner acoustic hole and the outer acoustic hole, make the internal sound flow more stable, reduce turbulent kinetic energy, and further reduce noise; or to keep the overall structural length unchanged while increasing the overall structural height, for example, increasing the height of the sensor packaging structure by 10 μm or 20 μm, so as to enlarge its inner cavity, reduce turbulent kinetic energy, and further reduce noise and improve SNR performance.

However, whether the sensor packaging structure is lengthened or heightened, the size of the sensor packaging structure needs to be increased, which undoubtedly increases its occupied volume and is not conducive to the design requirements of product miniaturization and being lightweight and thin.

### SUMMARY

A main objective of the present application is to provide a sensor packaging structure, a sensor, and an electronic device, aiming to solve the technical problem that existing approaches for improving SNR of sensor packaging structures are not conducive to design requirements of product miniaturization and being lightweight and thin.

To achieve the above objectives, the sensor packaging structure provided in the present application includes:
a housing with one end being provided with an opening;
a substrate provided over the opening and forming an encapsulation cavity with the housing, a first acoustic hole being provided on the substrate and communicating with the encapsulation cavity;
a sensing component accommodated in the encapsulation cavity, the sensing component including a mounting plate, a sensor chip and a signal processing chip installed side by side on the mounting plate, the sensor chip being electrically connected to the signal processing chip, the sensor chip having a vibration cavity, a second acoustic hole being provided on the mounting plate to communicate the vibration cavity and the encapsulation cavity, and the second acoustic hole being offset from the first acoustic hole; and
a waterproof membrane accommodated in the encapsulation cavity and located between the substrate and the sensing component, the waterproof membrane blocking the first acoustic hole, and the first acoustic hole being inclined toward the second acoustic hole in a direction adjacent to the waterproof membrane to compensate for misalignment between the first acoustic hole and the second acoustic hole.

In an embodiment, a cross-sectional area of the first acoustic hole increases in a direction toward the waterproof membrane.

In an embodiment, a wall of the first acoustic hole is a smooth and continuous wall.

In an embodiment, the first acoustic hole is a frustum-shaped hole.

In an embodiment, an angle between the wall of the first acoustic hole and a horizontal plane is 30° to 45°.

In an embodiment, an end of the first acoustic hole distant from the waterproof membrane forms a straight hole.

In an embodiment, the substrate includes a first circuit board and a second circuit board stacked together, the first circuit board being bonded to the second circuit board, one end of the housing having the opening is connected to the first circuit board, the mounting plate is supported on a side of the first circuit board distant from the second circuit board, the first circuit board forms a mounting cavity for mounting the waterproof membrane, the mounting cavity is part of the encapsulation cavity, the first acoustic hole penetrates the second circuit board, and the waterproof membrane is installed on a side of the second circuit board facing the first circuit board.

In an embodiment, a first copper layer is laid on the side of the second circuit board facing the first circuit board, and the first acoustic hole penetrates the first copper layer; and the first circuit board is annular to form the mounting cavity, the waterproof membrane is installed on the first copper layer, and a gap is formed between the waterproof membrane and an inner wall of the first circuit board.

In an embodiment, the first copper layer has a first avoidance hole formed at a position corresponding to the first acoustic hole, and the first avoidance hole surrounds the first acoustic hole.

In an embodiment, a distance between a wall of the first avoidance hole and a wall of the first acoustic hole at an end facing the first circuit board is 0.08 mm to 0.1 mm.

In an embodiment, an annular support plate is provided between the waterproof membrane and the first copper layer, one end of the annular support plate is bonded to the first copper layer, and an end of the annular support plate distant from the first copper layer supports and bonds the waterproof membrane.

In an embodiment, a second copper layer is laid on a side of the second circuit board distant from the first copper layer, a second avoidance hole is formed on the second copper layer corresponding to a position of the first acoustic hole, and the second avoidance hole surrounds the first acoustic hole.

In an embodiment, the waterproof membrane is a waterproof and breathable membrane.

The present application further provides a sensor, which includes the sensor packaging structure described above, and the sensor chip is a microelectromechanical acoustic sensor chip.

The present application further provides an electronic device that includes the sensor described above.

The first acoustic hole of the sensor packaging structure of the present application is inclined toward the second acoustic hole in a direction adjacent to the waterproof membrane to compensate for the misalignment difference between the first acoustic hole and the second acoustic hole, such that as many regions of the second acoustic hole as possible overlap and intersect with the region of the first acoustic hole, reducing the alignment deviation between the first acoustic hole and the second acoustic hole, thereby enabling sound entering the encapsulation cavity from the first acoustic hole to stably pass through the second acoustic hole into the vibration cavity, reducing turbulent kinetic energy, and further reducing noise and improving SNR performance. Moreover, the sensor packaging structure of the present application only needs to incline the first acoustic hole toward the second acoustic hole in a direction adjacent to the waterproof membrane, without needing to lengthen or heighten the sensor packaging structure, and thus without increasing its occupied volume, which is conducive to realizing miniaturization and lightweight and thin design requirements.

### BRIEF DESCRIPTION OF THE DRAWINGS

To more clearly illustrate the technical solutions in the embodiments of this application or the prior art, the drawings used in the description of the embodiments or the prior art will be briefly introduced below. Obviously, the drawings described below are only some embodiments of this application. For those skilled in the art, other drawings can be obtained based on the structures shown in these drawings without creative effort.

FIG. 1 is a cross-sectional schematic diagram of a sensor packaging structure according to an embodiment of the present application.

FIG. 2 is a cross-sectional schematic diagram of a partial structure in the sensor packaging structure according to an embodiment of the present application.

Realization of the objectives, functional features and advantages of the present application will be further described in conjunction with the embodiments and with reference to the drawings.

### DETAILED DESCRIPTION OF THE EMBODIMENTS

The technical solutions in embodiments of the present application will be clearly and completely described below in conjunction with the accompanying drawings in the embodiments of the present application. Apparently, the described embodiments are only some of the embodiments of the present application, rather than all embodiments. All other embodiments obtained by those skilled in the art based on the embodiments in the present application without creative effort shall fall within the protection scope of the present application.

It should be noted that all directional indications (such as up, down, left, right, front, rear, etc.) in the embodiments of the present application are only used to explain the relative position relationships, movement situations, and the like among various components in a specific posture (as shown in the accompanying drawings). If the specific posture changes, the directional indications will change accordingly.

In addition, the descriptions involving “first”, “second”, and the like in the present application are only for descriptive purposes, and shall not be construed as indicating or implying their relative importance or implicitly indicating the number of technical features referred to. Therefore, features defined with “first” and “second” may explicitly or implicitly include at least one such feature. In addition, technical solutions among the embodiments may be combined with each other, but must be based on being implementable by those skilled in the art. When the combination of technical solutions is contradictory or cannot be implemented, such combination of technical solutions shall be deemed not to exist and shall not fall within the claimed protection scope of the present application.

The present application provides a sensor packaging structure 100.

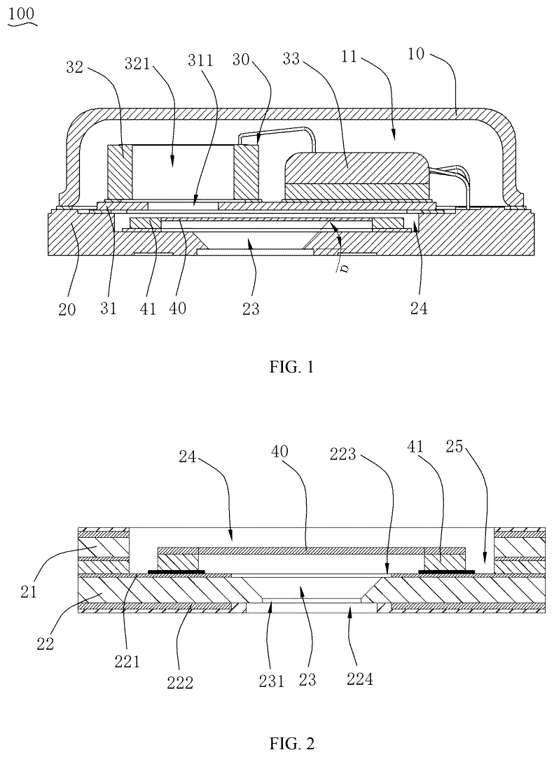

As shown in FIG. 1 and FIG. 2, the sensor packaging structure 100 in this embodiment includes a housing 10, a substrate 20, a sensing component 30, and a waterproof membrane 40. One end of the housing 10 is provided with an opening; the substrate 20 is provided over the opening and forms an encapsulation cavity 11 with the housing 10, and a first acoustic hole 23 communicating with the encapsulation cavity 11 is provided on the substrate 20; the sensing component 30 is accommodated in the encapsulation cavity 11, the sensing component 30 includes a mounting plate 31, and a sensor chip 32 and a signal processing chip 33 installed side by side on the mounting plate 31, the sensor chip 32 is electrically connected to the signal processing chip 33, the sensor chip 32 has a vibration cavity 321, a second acoustic hole 311 communicating the vibration cavity 321 and the encapsulation cavity 11 is provided on the mounting plate 31, and the second acoustic hole 311 is offset from the first acoustic hole 23; the waterproof membrane 40 is accommodated in the encapsulation cavity 11 and located between the substrate 20 and the sensing component 30, the waterproof membrane 40 blocks the first acoustic hole 23, and the first acoustic hole 23 is inclined toward the second acoustic hole 311 in a direction adjacent to the waterproof membrane 40 to compensate for misalignment between the first acoustic hole 23 and the second acoustic hole 311.

In an embodiment, a lower end of the housing 10 is provided with an opening, and the substrate 20 is located below the housing 10 and provided over the opening, so as to form the encapsulation cavity 11 with the housing 10 to accommodate the sensing component 30 and the waterproof membrane 40 therein, with a compact structure. In order to realize a waterproof function, a waterproof membrane 40 is arranged between the sensing component 30 and the substrate 20, and the waterproof membrane 40 blocks the first acoustic hole 23 to play a waterproof role. The first acoustic hole 23 of the substrate 20 communicates with the encapsulation cavity 11, and further communicates with the second acoustic hole 311 and the vibration cavity 321. From the positional relationship among the first acoustic hole 23, the second acoustic hole 311, and the housing 10, the first acoustic hole 23 can serve as an outer acoustic hole, and the second acoustic hole 311 can serve as an inner acoustic hole.

When the sensor packaging structure 100 is in use, external sound enters the encapsulation cavity 11 through the first acoustic hole 23 to input a vibration signal or a pressure signal into the encapsulation cavity 11, the waterproof membrane 40 is excited by the vibration signal or the pressure signal, the waterproof membrane 40 generates vibration, and transmits the vibration to the vibration cavity 321 of the sensor chip 32 through the second acoustic hole 311, such that a diaphragm of the sensor chip 32 vibrates, acoustic energy is converted into mechanical energy, and during the vibration process of the diaphragm, a pressure difference between the diaphragm and a back electrode of the sensor chip 32 changes, thereby outputting an alternating current signal to the signal processing chip 33 to realize a process of converting microphone acoustic energy into electrical energy. In an embodiment, the sensor chip 32 is a MEMS chip, and the signal processing chip 33 is an ASIC chip.

The sensor chip 32 and the signal processing chip 33 of the sensing component 30 are installed side by side on the mounting plate 31, without increasing the space occupied in the height direction of the encapsulation cavity 11, which is conducive to realizing a lightweight and thin design. Since the sensor chip 32 and the signal processing chip 33 are installed side by side, the sensor chip 32 deviates from a central position of the mounting plate 31, and the second acoustic hole 311 needs to be provided on the mounting plate 31 at a position directly corresponding to the sensor chip 32, that is, the second acoustic hole 311 deviates from the central position of the mounting plate 31, and due to structural design requirements, the first acoustic hole 23 needs to be located at the central position of the substrate 20, such that the first acoustic hole 23 and the second acoustic hole 311 are distributed in an offset manner, so as to improve the rationality of the overall structural design.

In this embodiment, the first acoustic hole 23 of the sensor packaging structure 100 is inclined toward the second acoustic hole 311 in a direction adjacent to the waterproof membrane 40 to compensate for the misalignment difference between the first acoustic hole 23 and the second acoustic hole 311, that is, the first acoustic hole 23 is inclined from bottom to top toward the direction of the second acoustic hole 311, so as to compensate for the misalignment difference between the first acoustic hole 23 and the second acoustic hole 311, such that as many regions of the second acoustic hole 311 as possible overlap and intersect with the region of the first acoustic hole 23, reducing the alignment deviation between the first acoustic hole 23 and the second acoustic hole 311, thereby enabling sound entering the encapsulation cavity 11 from the first acoustic hole 23 to stably pass through the second acoustic hole 311 into the vibration cavity 321, reducing turbulent kinetic energy, and further reducing noise and improving SNR performance. Moreover, in this embodiment, the sensor packaging structure 100 only needs to incline the first acoustic hole 23 toward the second acoustic hole 311 in a direction adjacent to the waterproof membrane 40, without needing to lengthen or heighten the sensor packaging structure 100, and thus without increasing its occupied volume, which is conducive to realizing miniaturization and lightweight and thin design requirements.

The sensor packaging structure 100 in this embodiment can be applied to electronic devices such as mobile phones, bracelets, watches, smart glasses, and earphones. Since it has advantages of miniaturization and being lightweight and thin, it is particularly suitable for products with higher requirements for miniaturization and being lightweight and thin, such as watches, smart glasses, and earphones.

In an embodiment, the first acoustic hole 23 is gradually widened in a direction toward the waterproof membrane 40, that is, the first acoustic hole 23 gradually expands from bottom to top, so as to further improve the stability of sound flow while compensating for the misalignment difference between the first acoustic hole 23 and the second acoustic hole 311, reduce turbulent kinetic energy, and further reduce noise and improve SNR performance.

In an embodiment, a wall of the first acoustic hole 23 is a smooth and continuous wall, and sound can flow smoothly and stably along the wall of the first acoustic hole 23, further reducing turbulent kinetic energy.

As shown in FIG. 1 and FIG. 2, in an embodiment, the first acoustic hole 23 is a frustum-shaped hole, which has a simple structure, is convenient for processing and forming, reduces cost, and is more conducive to reducing turbulent kinetic energy. Further, an angle between a wall of the first acoustic hole 23 and a horizontal plane is 30° to 45°. As shown in FIG. 1, the angle between the wall of the first acoustic hole 23 and the horizontal plane is α, and α=30° to 45°, which facilitates processing while ensuring that the wall of the first acoustic hole 23 is appropriately inclined, neither excessively inclined nor insufficiently inclined, thereby ensuring the stability of sound flow. In an embodiment, the angle between the wall of the first acoustic hole 23 and the horizontal plane is 30°.

It can be understood that a straight hole 231 is easier to process than a frustum-shaped hole. In this embodiment, an end of the first acoustic hole 23 distant from the waterproof membrane 40 forms the straight hole 231, that is, a bottom end of the first acoustic hole 23 forms the straight hole 231, so as to reduce the processing difficulty of the first acoustic hole 23.

In an embodiment, the substrate 20 comprises a first circuit board 21 and a second circuit board 22 stacked together, the first circuit board 21 is bonded to the second circuit board 22 through an adhesive layer, one end of the housing 10 having the opening is connected to the first circuit board 21, the mounting plate 31 is supported on a side of the first circuit board 21 distant from the second circuit board 22, the first circuit board 21 forms a mounting cavity 24 for mounting the waterproof membrane 40, the mounting cavity 24 is part of the encapsulation cavity 11, the first acoustic hole 23 penetrates the second circuit board 22, and the waterproof membrane 40 is installed on a side of the second circuit board 22 facing the first circuit board 21.

As shown in FIG. 2, the first circuit board 21 is pressed above the second circuit board 22, and the first circuit board 21 and the second circuit board 22 are bonded through an adhesive layer. The adhesive layer may be made of a non-flowable PP (polypropylene) material in the prior art to avoid the phenomenon of glue tumor caused by pressing of the first circuit board 21 and the second circuit board 22. One end of the housing 10 having the opening, that is, a bottom end of the housing 10, is connected to the first circuit board 21. The mounting plate 31 is supported on a top side of the first circuit board 21, and the first circuit board 21 encloses the mounting cavity 24. The mounting cavity 24 is part of the encapsulation cavity 11, which facilitates installation of the waterproof membrane 40 in the mounting cavity 24. The first acoustic hole 23 penetrates the second circuit board 22 to communicate with the mounting cavity 24. The waterproof membrane 40 is installed on a side of the second circuit board 22 facing the first circuit board 21, that is, the waterproof membrane 40 is installed on an upper side of the first mounting plate 31 to block the first acoustic hole 23, and the structural design is reasonable.

In an embodiment, a first copper layer 221 is laid on a side of the second circuit board 22 facing the first circuit board 21, and the first acoustic hole 23 penetrates the first copper layer 221. The first circuit board 21 is annular to enclose the mounting cavity 24. The waterproof membrane 40 is installed on the first copper layer 221, and a gap 25 is formed between the waterproof membrane 40 and an inner wall of the first circuit board 21.

As shown in FIG. 2, the first copper layer 221 is laid on an upper side of the second circuit board 22, and the first acoustic hole 23 penetrates the first copper layer 221. An inner cavity of the first circuit board 21 forms the mounting cavity 24, and the first circuit board 21 surrounds an outer periphery of the waterproof membrane 40. The waterproof membrane 40 is installed on the first copper layer 221, and a gap 25 is formed between the waterproof membrane 40 and an inner wall of the first circuit board 21. When optical detection of the waterproof membrane 40 is required to detect whether it is damaged, has foreign matters, or has glue overflow at a periphery connected to other structures, the first copper layer 221 exposed at the gap 25 can present a bright surface under an optical camera, while the waterproof membrane 40 presents a dark surface, so as to realize optical detection of the waterproof membrane 40 through contrast between the first copper layer 221 and the waterproof membrane 40.

In an embodiment, the waterproof membrane 40 is a waterproof and breathable membrane, which has a breathable function while being waterproof, facilitating sound transmission. In another embodiment, the waterproof membrane 40 is a non-breathable waterproof membrane, so as to improve a driving force of sound entering the encapsulation cavity 11 from the first acoustic hole 23 on the waterproof membrane 40.

In an embodiment, the first copper layer 221 has a first avoidance hole 223 formed at a position corresponding to the first acoustic hole 23, and the first avoidance hole 223 surrounds the first acoustic hole 23. During processing of the first acoustic hole 23, drawing defects may be caused to a periphery of the first copper layer 221 corresponding to the first acoustic hole 23 and affect sound flow. Therefore, after the first acoustic hole 23 is processed, the periphery of the first copper layer 221 corresponding to the first acoustic hole 23 is etched to form the first avoidance hole 223 surrounding the first acoustic hole 23, and the structural design is reasonable.

Further, a distance between a wall of the first avoidance hole 223 and a wall of the first acoustic hole 23 at an end facing the first circuit board 21 is 0.08 mm to 0.1 mm. In an embodiment, a shape of the first avoidance hole 223 is consistent with a shape of an end of the first acoustic hole 23 facing the first circuit board 21, that is, an upper end wall, and the distance between the wall of the first avoidance hole 223 and the upper end wall of the first acoustic hole 23 is 0.08 mm to 0.1 mm, so as to etch in place, eliminate drawing defects, and ensure stability of sound flow. In an embodiment, the distance between the wall of the first avoidance hole 223 and the upper end wall of the first acoustic hole 23 is 0.1 mm, which is convenient for manufacturing.

In an embodiment, an annular support plate 41 is provided between the waterproof membrane 40 and the first copper layer 221, one end of the annular support plate 41 is bonded to the first copper layer 221, and an end of the annular support plate 41 distant from the first copper layer 221 supports and bonds the waterproof membrane 40.

As shown in FIG. 1 and FIG. 2, a bottom of the waterproof membrane 40 is supported and bonded on a top end of the annular support plate 41, and a bottom of the annular support plate 41 is bonded on the first copper layer 221, so as to fix the waterproof membrane 40 above the first acoustic hole 23 and block the first acoustic hole 23. Moreover, due to the provision of the annular support plate 41, a position of the waterproof membrane 40 can be raised, such that a spacing between the waterproof membrane 40 and the first acoustic hole 23 is increased, which can reduce turbulent kinetic energy.

In an embodiment, a second copper layer 222 is laid on a side of the second circuit board 22 distant from the first copper layer 221, a second avoidance hole 224 is formed on the second copper layer 222 corresponding to a position of the first acoustic hole 23, and the second avoidance hole 224 surrounds the first acoustic hole 23.

As shown in FIG. 2, a second copper layer 222 is laid on a side of the second circuit board 22 distant from the first copper layer 221, that is, a lower side, and a second avoidance hole 224 is formed on the second copper layer 222 corresponding to a position of the first acoustic hole 23, and the second avoidance hole 224 surrounds the first acoustic hole 23. The second avoidance hole 224 may be a pre-reserved avoidance hole before processing the first acoustic hole 23, so as to avoid interference with processing equipment during processing of the first acoustic hole 23.

The present application further provides a sensor, and the sensor comprises the above-mentioned sensor packaging structure 100. Since the sensor adopts all technical solutions of the above embodiments, the sensor at least has all beneficial effects brought by the technical solutions of the above embodiments, which are not repeated here. In an embodiment, the sensor chip 32 is a microelectro-acoustic sensor chip, which is more suitable for acoustic devices.

The present application further provides an electronic device, and the electronic device comprises the above sensor. The electronic device may be a mobile phone, a bracelet, a watch, smart glasses, an earphone, or the like. Since the electronic device adopts all technical solutions of the above embodiments, the electronic device at least has all effects brought by the technical solutions of the above embodiments, which are not repeated here.

The foregoing description is merely exemplary embodiments of the present application and is not intended to limit a patent scope of the present application. Any equivalent structural changes made under a technical concept of the present application by using contents of the specification and the drawings of the present application, or any direct or indirect application of the technical solutions to other related technical fields, fall within a protection scope of the present application.

What is claimed is:

1. A sensor packaging structure, comprising:
a housing with one end being provided with an opening;
a substrate provided over the opening and forming an encapsulation cavity with the housing, a first acoustic hole being provided on the substrate and communicating with the encapsulation cavity;
a sensing component accommodated in the encapsulation cavity, the sensing component comprising a mounting plate, a sensor chip and a signal processing chip installed side by side on the mounting plate, the sensor chip being electrically connected to the signal processing chip, the sensor chip having a vibration cavity, a second acoustic hole being provided on the mounting plate to communicate the vibration cavity and the encapsulation cavity, and the second acoustic hole being offset from the first acoustic hole; and
a waterproof membrane accommodated in the encapsulation cavity and located between the substrate and the sensing component, the waterproof membrane blocking the first acoustic hole, and the first acoustic hole being inclined toward the second acoustic hole in a direction adjacent to the waterproof membrane to compensate for misalignment between the first acoustic hole and the second acoustic hole.

2. The sensor packaging structure according to claim 1, wherein a cross-sectional area of the first acoustic hole increases in a direction toward the waterproof membrane.

3. The sensor packaging structure according to claim 2, wherein a wall of the first acoustic hole is a smooth and continuous wall.

4. The sensor packaging structure according to claim 3, wherein the first acoustic hole is a frustum-shaped hole.

5. The sensor packaging structure according to claim 4, wherein an angle between the wall of the first acoustic hole and a horizontal plane is 30° to 45°.

6. The sensor packaging structure according to claim 4, wherein an end of the first acoustic hole distant from the waterproof membrane forms a straight hole.

7. The sensor packaging structure according to claim 1, wherein:
the substrate comprises a first circuit board and a second circuit board stacked together, the first circuit board being bonded to the second circuit board, one end of the housing having the opening is connected to the first circuit board, the mounting plate is supported on a side of the first circuit board distant from the second circuit board, the first circuit board forms a mounting cavity for mounting the waterproof membrane, the mounting cavity is part of the encapsulation cavity, the first acoustic hole penetrates the second circuit board, and the waterproof membrane is installed on a side of the second circuit board facing the first circuit board.

8. The sensor packaging structure according to claim 7, wherein:
a first copper layer is laid on the side of the second circuit board facing the first circuit board, and the first acoustic hole penetrates the first copper layer; and
the first circuit board is annular to form the mounting cavity, the waterproof membrane is installed on the first copper layer, and a gap is formed between the waterproof membrane and an inner wall of the first circuit board.

9. The sensor packaging structure according to claim 7, wherein the first copper layer has a first avoidance hole formed at a position corresponding to the first acoustic hole, and the first avoidance hole surrounds the first acoustic hole.

10. The sensor packaging structure according to claim 9, wherein a distance between a wall of the first avoidance hole and a wall of the first acoustic hole at an end facing the first circuit board is 0.08 mm to 0.1 mm.

11. The sensor packaging structure according to claim 8, wherein an annular support plate is provided between the waterproof membrane and the first copper layer, one end of the annular support plate is bonded to the first copper layer, and an end of the annular support plate distant from the first copper layer supports and bonds the waterproof membrane.

12. The sensor packaging structure according to claim 7, wherein a second copper layer is laid on a side of the second circuit board distant from the first copper layer, a second avoidance hole is formed on the second copper layer corresponding to a position of the first acoustic hole, and the second avoidance hole surrounds the first acoustic hole.

13. The sensor packaging structure according to claim 1, wherein the waterproof membrane is a waterproof and breathable membrane.

14. A sensor, comprising the sensor packaging structure according to claim 1, wherein the sensor chip is a microelectro-acoustic sensor chip.

15. An electronic device, comprising the sensor according to claim 14.
